(19) United States
(12) Patent Application Publication
(10) Pub. No.: US 2003/0141017 A1
(43) Pub. Date: Jul. 31, 2003

(54) Plasma processing apparatus

(75) Inventor: Toshiaki Fujisato, Nirasaki City (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Tokyo (JP)

(21) Appl. No.: 10/354,127

(22) Filed: Jan. 30, 2003

(30) Foreign Application Priority Data
Jan. 30, 2002 (JP) 2002-21829

(51) Int. Cl. C23C 16/00; C03C 15/00; C23F 1/00

(52) U.S. Cl. 156/345.47; 118/723 E; 216/44

(57) ABSTRACT

A plasma processing apparatus has a process chamber, an upper electrode, a susceptor which can elevate up and down and serves as a lower electrode and on which a work is placed, a feeder bar connected to an upper surface of the upper electrode and an insulating film formed on the feeder bar and the upper surface of the upper electrode, a bellows which is connected at one end to the susceptor and at the other end to a bottom portion of the process chamber and maintain the vacuum state inside the process chamber. The insulating film has a porous structure formed by thermal-spraying insulating material, e.g., PTFE toward the feeder bar and the upper electrode. The bellows is formed of high purity aluminum or nickel.

### BACKGROUND OF THE INVENTION

1. Field of the Invention

The present invention relates to a plasma processing apparatus.

2. Description of the Related Art

A fabrication process for semiconductor substrates, liquid crystal substrates and so forth uses a plasma processing apparatus which performs a surface process on those substrates using plasma. Available plasma processing apparatuses include, for example, a plasma etching apparatus which performs an etching process on a substrate and plasma CVD (Chemical Vapor Deposition) which performs CVD. Of those plasma-processing apparatuses, a parallel plate plasma processing apparatus is popular because of its excellent uniform processing and relatively simple structure.

Japanese Patent Laid-Open No. 2001-93884 discloses one example of such a parallel plate plasma processing apparatus. The contents of this publication are incorporated herein by reference.

A parallel plate plasma processing apparatus is structured to have two electrode parallel plates which face each other in parallel. Of the two electrodes, the lower electrode has a susceptor on which a work to be processed can be placed. The upper electrode has an electrode plate which has multiple gas openings in its side that faces the lower electrode. The upper electrode is connected to a supply source of a process gas so that at the time of performing a process, the process gas is supplied to space (plasma generating space) between the upper and lower electrodes from the upper electrode side via the gas openings in the electrode plate. As high-frequency electric power is supplied to the upper electrode, the process gas supplied through the gas openings is turned into plasma by which a predetermined surface process is performed on a work to be processed.

This parallel plate plasma processing apparatus has the following shortcomings (1) to (4).

(1) A feeder bar for supplying high-frequency electric power is connected to the upper electrode. The outer surface of the feeder bar is covered with an insulating film to insulate the feeder bar from what surrounds the bar. In general, PTFE (Poly-Tetra-Fluoro-Ethyrene) which is excellent in insulation is used for the insulating film.

Even PTFE, however, has a limited specific dielectric constant of about 2.1 in case where the insulating film is formed of PTFE. To insulate the feeder bar from the surrounding, therefore, it is necessary to provide a sufficient distance between the feeder bar and the surrounding. The longer the distance between the feeder bar and the surrounding becomes, however, the greater the dielectric loss becomes at the time of plasma processing.

As apparent from the above, the conventional plasma processing apparatus has a difficulty in reducing the dielectric loss while adequately insulating the feeder bar from the surrounding.

(2) Generally, the chamber is constructed of aluminum which has an excellent conductivity and its inner surface undergoes an alumite process in order to guarantee insulation and plasma resistance or the like. To suppress generation of particles, it is desirable that the inner surface of the chamber should be as smooth as possible. A method of manufacturing the conventional chamber will be discussed below referring to FIGS. 8A to 8H and FIG. 9. FIGS. 8A to 8D are diagrams of the inner surface of a cylindrical base member in individual steps in a method of manufacturing a conventional chamber as seen from the front, and FIGS. 8E to 8H are cross-sectional views of the base member in the individual steps in the conventional chamber manufacturing method. FIG. 9 is a flowchart for explaining the conventional chamber manufacturing method.

First, an aluminum bulk is cut to from a cylindrical base member 47. Then, as shown in FIGS. 8A and 8D, the surface of the base member 47, is smoothed to have a predetermined roughness by mechanical working (step 901). The mechanical working forms cracks 49 on the inner surface of the base member 47 as shown in FIG. 8D.

Next, as shown in FIGS. 8B and 8E, the inner surface of the base member 47 is manually polished to about 15 μm, thus removing the cracks 49 formed on the inner surface (step 902). The manual polishing produces polishing spots 50 on the inner surface of the base member 47 as shown in FIG. 8B.

Subsequently, as shown in FIGS. 8C and 8F, the base member 47 is immersed in an aqueous alkaline solution (e.g., a sodium hydroxide (NaOH) solution with a concentration of about 10%) to etch about 1 μm to 2 μm the inner surface (step 903).

Finally, as shown in FIGS. 8D and 8H, the base member 47 is immersed into an acid solution (e.g., a nitrate solution with a concentration of about 10%) and a voltage is applied to the nitrate solution to carry out an electrolytic process, thereby forming an anodized film 48 (e.g., an alumite nitrate film) with a thickness of about 15 μm on the inner surface of the base member 47 (step 904). This completes the formation of the chamber.

To secure the thickness of the base member 47, the thickness of the inner surface that can be etched in step 902 is limited to about 1 μm to 2 μm. Etching of such a degree cannot remove the polishing spots 50 formed on the inner surface of the base member 47. Therefore, the roughness of the inner surface of the chamber to be manufactured might not reach to the level that could prevent generation of particles.

Even if the roughness that can prevent generation of particles is secured, the depths and directions of the polishing spots 50 vary as shown in FIG. 8B, so that an alumite process performed on the top surface may cause color irregularity 51 as shown in FIG. 8D. Alumite whose tone is thin suffers noticeable color irregularity 51, resulting in a poor appearance and a lower yield. Because the chamber could not be manufactured at a high yield, it was difficult to decrease the cost for manufacturing the chamber.

(3) A support is attached to the bottom of the lower electrode. Further, the center portion of the bottom of the support is covered with a bellows. Conventionally, the bellows is made of an iron material, such as stainless steel, or a resin or the like.

The bellows, if made of stainless steel, generates particles as it contacts a plasma or corrosive gas or the like, thereby causing metal contamination. The bellows, if made of a resin, has a limited working temperature range.

(4) To confine the generated plasma in the process space and acquire a high efficiency of plasma usage, a baffle plate is provided around the lower electrode. The baffle plate is made of a metal, and formed in a ring-like shape and is fixed to the wall of the chamber in such a way as to surround the lower electrode. The baffle plate has multiple narrow openings, such as slits or circular openings, formed therein to allow the gas flow throughthem but to transmission of the plasma.

To confine the plasma and secure the conductance (permeability) of the baffle plate at the same time, the baffle plate should desirably have minute and many narrow openings formed therein. A method of manufacturing the conventional baffle plate will be discussed by referring to FIGS. 10A and 10B.

A ring-shaped base member with a thickness of about 5 mm to 10 mm as shown in FIG. 10A is prepared and narrow openings are formed in the base member by machining as shown in FIG. 10B.

In case of forming narrow openings by machining, a base member with a certain thickness (about 5 mm to 10 mm) should be used from the viewpoint of the working load. In addition, the size, quantity, shape, etc. of the narrow openings have productional limits. In the machining process, therefore, desired minute and multiple narrow openings could not be formed in the baffle plate, which would make it difficult to acquire a high efficiency of plasma usage while securing the conductance.

### SUMMARY OF THE INVENTION

Accordingly, it is an object of the invention to provide a plasma processing apparatus which can process a work to be processed with a high plasma-using efficiency.

It is another object of the invention to provide a method of manufacturing a process chamber with a good appearance.

It is a further object of the invention to provide a plasma processing apparatus having a bellows difficult to cause metal contamination with corrosive gas.

It is a still further object of the invention to provide a method of manufacturing a baffle plate which can ensure a high plasma-using efficiency.

To achieve the objects, a plasma processing apparatus according to the first aspect of the invention comprises: a process chamber in which a predetermined process is performed on a work; a first electrode which is arranged in the process chamber and on which the work is to be placed; a second electrode facing to the first electrode; and a conductive member which is connected to the second electrode and supplies high-frequency electric power to the second electrode.

In this structure, an insulating film with a porous structure may be formed on surface of the conductive member and at least a part of a surface of the second electrode onto which the conductive member is connected.

In the structure of the first aspect, the conductive member and at least a part of a surface of the second electrode onto which the conductive member is connected may have an insulating film formed by thermal-spraying an insulating material onto the conductive member and the at least a part of a surface of the second electrode.

In the structure of the first modification of the first aspect, the insulating film may be formed by: performing thermal spray of an insulating material onto the conductive member and the at least a part of the second electrode to form a thermal-splayed film; and annealing the thermal-sprayed film every time the thermal-sprayed film with a predetermined thickness is formed.

In the structure of the second modification of the first aspect, the insulating material may be comprised of PTFE (Poly Tetra Fluoro Ethyrene).

In the structure of the second modification of the first aspect, surfaces of the conductive member and the at least a part of the second electrode may have a predetermined roughness in order to enhance adhesion of the insulating thermal-sprayed material.

In the structure of the second modification of the first aspect, surfaces of the conductive member and the at least a part of the second electrode may have a predetermined roughness by shotblasting.

In the structure of the first aspect, the process chamber may be manufactured by: smoothing an inner surface of a cylindrical base member by mechanical working; etching out cracks formed on the inner surface of the base member by the smoothing, the crack being formed by the mechanical working; and forming an insulating film on the inner surface of the base member after the cracks have been etched out.

In this structure, the insulating film may be a metal oxide film formed by anodizing.

In this structure, the base member may be made of aluminum and the insulating film may be an aluminum oxide film.

The plasma processing apparatus may further comprise a bellows which connects a bottom portion of the process chamber and the first electrode, the bellows being formed of high-purity aluminum, nickel, or alloy thereof.

The plasma processing apparatus may further comprise a baffle plate which is provided inside the process chamber and traps a generated plasma in a predetermined area in the process chamber, and the baffle plate being manufactured by: forming a photoresist film on a base member and patterning the photoresist film to have a plurality of openings; and forming a plurality of openings by etching the base member using the patterned photoresist film as an etching mask.

To achieve the objects, a plasma processing apparatus according to the second aspect of the invention comprises: an electrode facing to a susceptor on which a work is to be placed; a conductive member which is connected to the electrode and feeds high-frequency electric power to the electrode; and an insulating film formed on the conductive member and at least a part of a surface of the electrode onto which the conductive member is connected; the insulating film being formed by thermal-spraying an insulating material onto the conductive member and the at least a part a surface of the electrode.

To achieve the objects, a plasma processing apparatus according to the third aspect of the invention have a process chamber and performing a predetermined process on a work in the process chamber, the process chamber being manufactured by: smoothing an inner surface of a cylindrical base member by mechanical working; etching out cracks formed on the inner surface of the base member, the crack being formed by the mechanical working; and forming an insulating film on the inner surface of the base member after the cracks have been etched out.

To achieve the objects, a plasma processing apparatus according to the fourth aspect of the invention comprises: a process chamber in which a predetermined process is performed on a work; an electrode which is arranged in the process chamber and on which the work is placed; and a bellows which is connected to a bottom portion of the process chamber and the electrode; the bellows being formed of high-purity aluminum, nickel, or alloy thereof.

To achieve the objects, a plasma processing apparatus according to the fifth aspect of the invention comprises: a process chamber in which a predetermined process is performed on a work; and a baffle plate which is provided inside the process chamber and traps a generated plasma in a predetermined area in the process chamber, the baffle plate being manufactured by: forming a photoresist film on a base member and patterning the photoresist film to have a plurality of openings; and forming a plurality of openings by etching the base member using the patterned photoresist film as an etching mask.

To achieve the objects, a insulating film forming system according to the sixth aspect of the invention comprises a thermal spray unit which thermal-sprays an insulating material toward a target; a heating unit which heats up the thermal-sprayed material adhered to the target; and a control unit which performs a first control operation that makes the thermal spray unit to thermal-spray the insulating material toward the target during a predetermined time period so that an insulating film with a predetermined thickness is formed on the target, then performs a second control operation that makes the heating unit to heat the insulating film on the target during a predetermined time period so that the insulating film is melted and then cooling down the melted insulating film so that the insulating film is hardened, and repeats the first and second control operations until the insulating film having a desired thickness is formed on the target.

In the structure of the sixth aspect, the control unit may calculate, from the predetermined thickness and the desired thickness, number of times the first and second control operations should be repeated, and may repeat the first and second control operations by the calculated number of times.

To achieve the objects, a insulating film forming system according to the seventh aspect of the invention comprises: thermal-spraying insulating material toward a target during a predetermined time period so that an insulating film with a predetermined thickness is formed on the target, heating the insulating film on the target during a predetermined time period so that the insulating film is melted and then cooling down the melted insulating film so that the insulating film is hardened.

In the structure of the seventh aspect, the thermal-spraying, the melting, and the cooling may be repeated until the insulating film having a desired thickness is formed on the target.

To achieve the objects, a bellows, which is connected to, at one end, a bottom portion of a process chamber in which a predetermined process is performed on a work, and connected to, at another end, an electrode which is arranged in the process chamber and supports the work, maintains the vacuum state inside of the chamber thereby the predetermined process can be performed, the bellows being formed of high-purity aluminum, nickel, or alloy thereof.

To achieve the objects, a method of forming an insulating film according to the ninth aspect of the invention, comprises: performing thermal spray of an insulating material onto a conductive member which is connected to an electrode supporting a work and feeds high-frequency electric power to the electrode, and onto at least a part of a surface of the electrode onto which the conductive member is connected, to form a thermal-sprayed film; and annealing the thermal-splayed film every time the thermal-sprayed film with a predetermined thickness is formed.

To achieve the objects, a method of manufacturing a process chamber of a plasma processing apparatus wherein a predetermined process using a plasma is performed on a work, comprises: smoothing an inner surface of a cylindrical base member by mechanical working; etching out cracks formed on the inner surface of the base member, the crack being formed by the mechanical working; and forming an insulating film on the inner surface of the base member after the cracks have been etched out.

To achieve the objects, a method of manufacturing a baffle plate which is provided inside a process chamber in a plasma processing apparatus for performing a predetermined process on a work to be processed in the process chamber and traps a generated plasma in a predetermined area in the process chamber, according to the eleventh aspect of the invention, comprises: forming a photoresist film on a base member and patterning the photoresist film to have a plurality of openings; and forming a plurality of openings by etching the base member using the patterned photoresist film as an etching mask.

### BRIEF DESCRIPTION OF THE DRAWINGS

The objects and other objects and advantages of the present invention will become more apparent upon reading of the following detailed description and the accompanying drawings in which:

FIG. 1 is a diagram illustrating the structure of a plasma processing apparatus according to one embodiment of the invention;

FIGS. 2A to 2C are diagrams of the inner surface of a cylindrical base member of a chamber in individual steps in a method of manufacturing the chamber according to the invention as seen from the front, and FIGS. 2D to 2F are cross-sectional views of the base member in the individual steps in the chamber manufacturing method according to the invention;

FIG. 3 is a flowchart for explaining the chamber manufacturing method according to the invention;

FIGS. 4A to 4C are perspective views of a base member of a baffle plate in individual steps in a method of manufacturing a baffle plate according to the invention;

FIG. 5 is a flowchart for explaining the baffle plate manufacturing method according to the invention;

FIG. 6 is a structural diagram of an insulating film forming system which forms an insulating film by thermal spray of an insulating material;

FIG. 7 is a flowchart for explaining the operation of the insulating film forming system;

FIGS. 8A to 8D are diagrams of the inner surface of the cylindrical base member of the chamber in individual steps in a method of manufacturing a conventional chamber as seen from the front, and FIGS. 8E to 8H are cross-sectional views of the aluminum in the individual steps in the conventional chamber manufacturing method;

FIG. 9 is a flowchart for explaining the conventional chamber manufacturing method; and

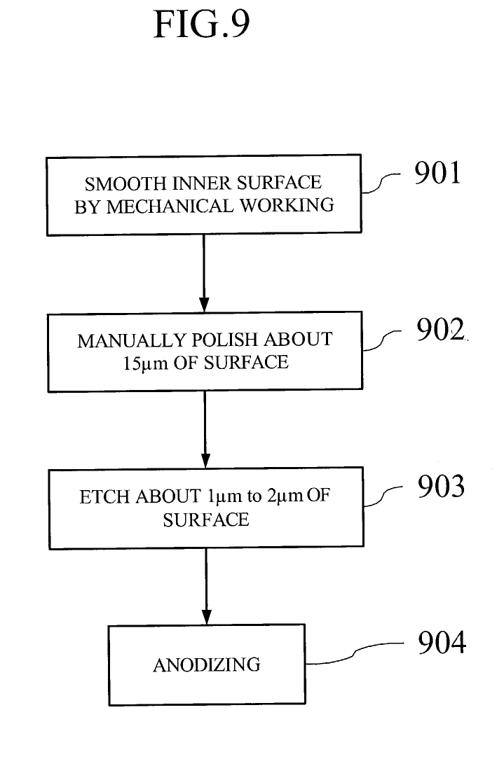

FIGS. 10A and 10B are perspective views of a base member in individual steps in a method of manufacturing a conventional baffle plate.

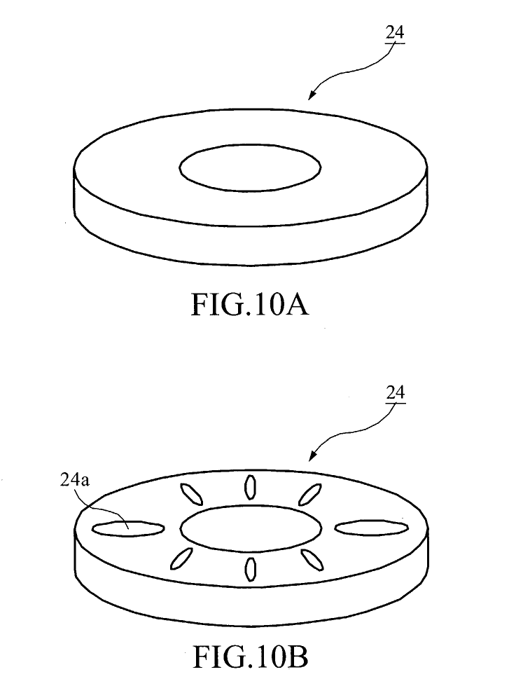

### DETAILED DESCRIPTION OF THE PREFERRED EMBODIMENT

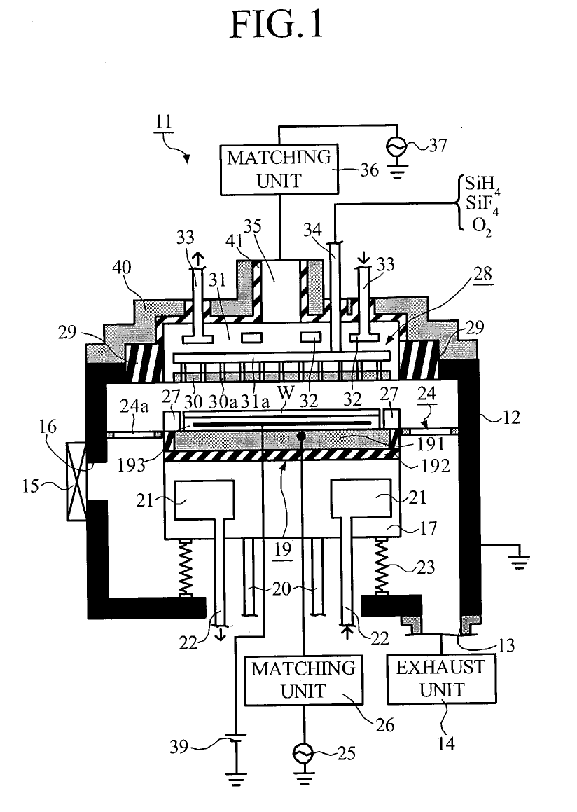

FIG. 1 shows the structure of a plasma processing apparatus 11 according to one embodiment of the invention. The plasma processing apparatus 11 is a so-called parallel plates plasma processing apparatus which has an upper electrode and a lower electrode facing each other, and has a capability of depositing an SiOF film or the like onto the major surface of, a to-be-processed object (work), such as a semiconductor wafer W (hereinafter referred to as “wafer W”).

The plasma processing apparatus 11 has a chamber 12 having an approximately cylindrical shape. The chamber 12 is made of a conductive material, such as aluminum. To ensure insulation and plasma resistance or the like, the inner surface of the chamber 12 is subjected to an alumite process (anodizing process).

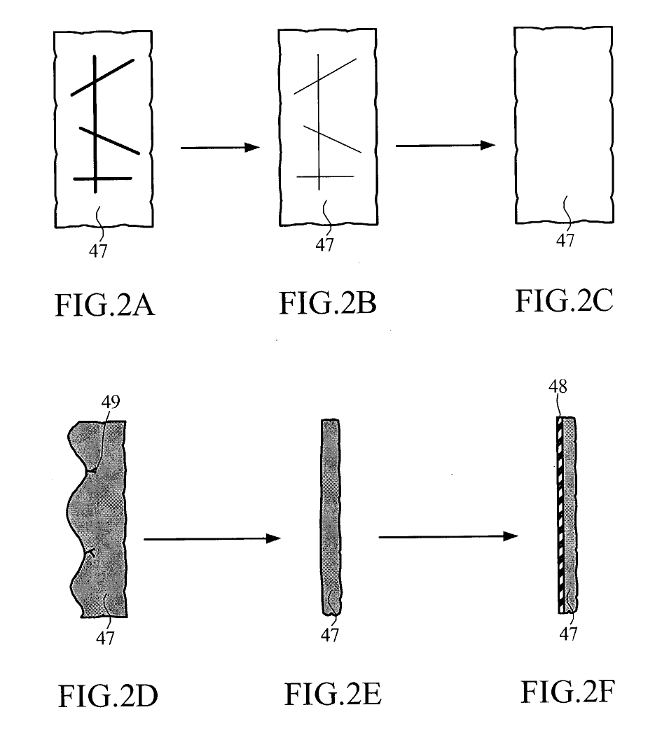

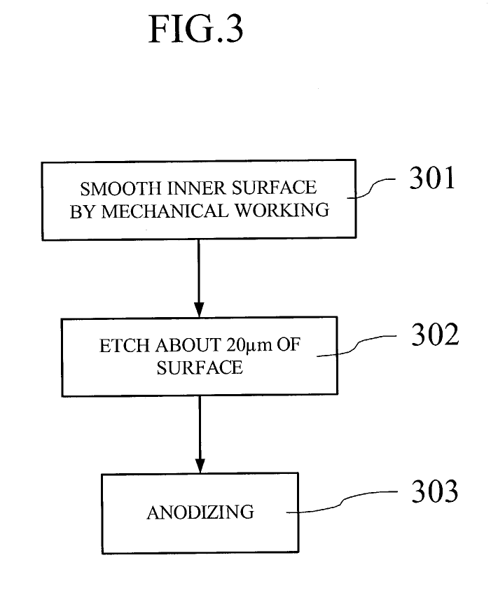

It is desirable that the inner surface of the chamber 12 should be made as smooth as possible in order to suppress generation of particles. The best mode for a method of manufacturing the chamber 12 will be discussed below referring to FIGS. 2A to 2F and FIG. 3. FIGS. 2A to 2C are diagrams of the inner surface of a cylindrical base member 47 in individual steps in a method of manufacturing the chamber 12 according to the invention as seen from the front, and FIGS. 2D to 2F are cross-sectional views of the base member 47 in the individual steps in the method of manufacturing the chamber 12 according to the invention. FIG. 3 is a flowchart for explaining the method of manufacturing the chamber 12.

First, an aluminum bulk is cut to from cylindrical base member 47 of the chamber 12. Then, as shown in FIGS. 2A and 2D, the inner surface of the base member 47, which is made of aluminum, is smoothed to a predetermined roughness by mechanical working (step 301). As shown in FIG. 2A. Gracks 49 are formed inevitably in the inner surface of the base member 47 due to the mechanical working.

Next, as shown in FIGS. 2B and 2E, the base member 47 is immersed in an aqueous alkaline solution (e.g., a sodium hydroxide (NaOH) solution with a concentration of about 10%) for, e.g., about one minute to etch about 20 μm the inner surface (step 302). This etching removes the cracks 49, formed by the mechanical working, as shown in FIG. 2E.

Finally, as shown in FIGS. 2C and 2F, the base member 47 is immersed into an acid solution (e.g., a nitrate solution with a concentration of about 10%) and a voltage is applied to the nitrate solution to carry out an electrolytic process, thereby forming a n anodized film 48 (e.g., an alumite nitrate film) with a thickness of about 15 μm on the inner surface of the base member 47 (step 303). This completes the formation of the chamber 12.

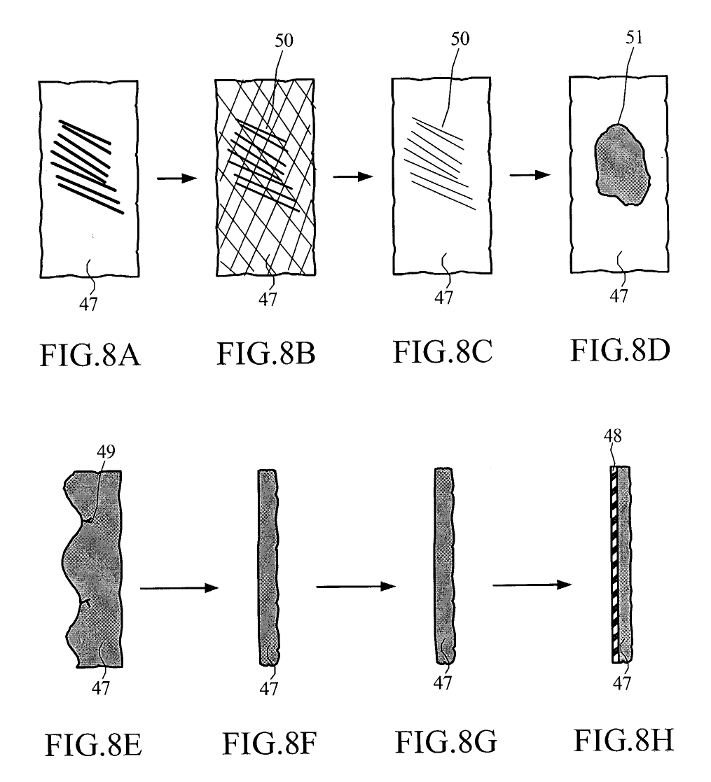

The above-described manufacturing method does not require a step of manually polishing the inner surface so that polishing spots 50 as shown in FIG. 8B are not formed on the inner surface. It is therefore possible to form the inner surface of the chamber 12 smoother than that of the conventional chamber. As polishing spots 50 are not formed, an alumite (anodizing) process does not cause color irregularity 51, thus making it possible to prevent a reduction in the yield which would otherwise be caused by a poor appearance. Further, the elimination of a manual work or the like can reduce the substantial number of steps and improve the throughput, which results in a reduction in manufacturing cost.

As shown in FIG. 1, the chamber 12 is grounded.

An exhaust port 13 is provided at the bottom portion of the chamber 12. An exhaust unit 14 is connected to the exhaust port 13. The exhaust unit 14 has a vacuum pump, such as a turbo molecular pump, which can evacuate the chamber 12 to a predetermined depressurized environment, such as a pressure of 0.01 Pa or lower.

A load/unload port 16 provided with an openable/closable gate valve 15 is provided on the sidewall of the chamber 12. While the gate valve 15 at the load/unload port 16 is opened, loading and unloading of the wafer W is possible between the chamber 12 and an unillustrated load lock chamber.

A susceptor support 17 with an approximately columnar shape is provided on the bottom center portion in the chamber 12. A susceptor 19 which serves as a wafer table (work table) is provided on the susceptor support 17. The susceptor support 17 is connected via a shaft 20 to an elevating mechanism (not shown) provided below the chamber 12 and is so constructed as to be elevatable up and down together with the susceptor 19.

A lower refrigerant chamber 21 is provided inside the susceptor support 17. A lower refrigerant tube 22 is connected to the lower refrigerant chamber 21. A refrigerant, such as fluorinert, circulates in the lower refrigerant chamber 21 and the lower refrigerant tube 22. As the refrigerant circulates in the lower refrigerant chamber 21 and the lower refrigerant tube 22, the susceptor 19 and the side of the wafer W can be controlled to the desired temperature.

The lower center portion of the susceptor support 17 is covered with a bellows 23. The bellows 23 is made of high purity (e.g., purity of 85% or over, desirably purity of 99.2% or over) nickel or aluminum or an alloy of them which has a high plasma resistance or high corrosion resistance.

As the bellows 23 is made of a metal with a high plasma resistance, its contact with plasma does not generate particles. Even if a corrosive gas (e.g., a fluorine-based gas which is used to clean the plasma processing apparatus) is supplied inside of the chamber 12, less particle is generated, because bellows 23 has a high corrosive resistance. Accordingly, the bellows 23 can prevent metal contamination. Further, as the bellows 23 is made of a metal, it has a wider working temperature range than a bellows made of a resin.

The upper end of the bellows 23 is welded to the bottom of the susceptor support 17, and the lower end is welded to the bottom of the chamber 12. As the bellows 23 is stretched or contracted in accordance with the elevating action of the susceptor support 17, the plasma processing apparatus 11 can maintain the vacuum state in the chamber 12.

A baffle plate 24 is provided around the susceptor 19. The baffle plate 24, which is made of a ring-shape metal and has a thickness of about 1 mm to 2 mm. The baffle plate 24 is secured to the sidewall of the chamber 12 in such a way as to enclose the susceptor 19 and traps or confines the generated plasma in the process space. The baffle plate 24 may be secured to the sidewall of the chamber 12 so as to enclose the susceptor support 17.

The baffle plate 24 has plurality of narrow openings 24a, such as slits or circular openings, formed therein so as to allow the gas flow throughthem but to the plasma.

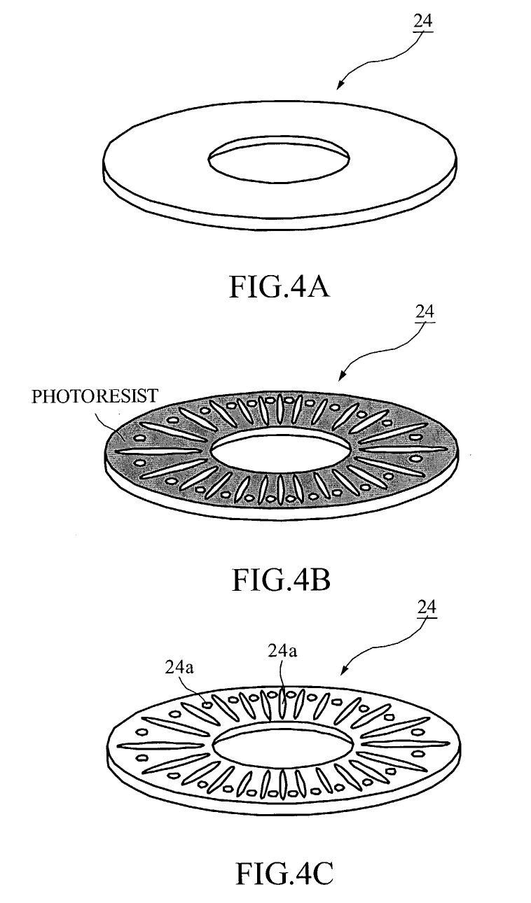

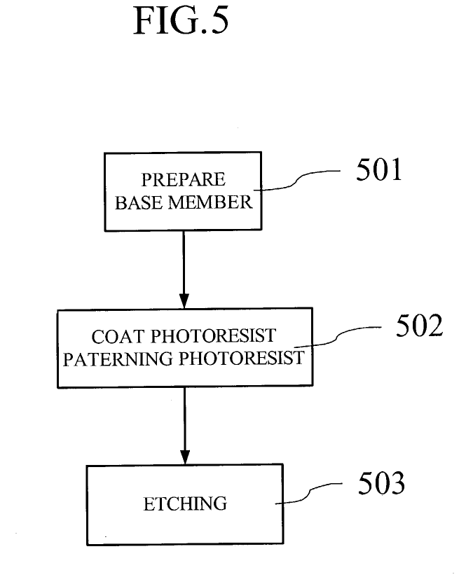

To confine the plasma and secure the conductance (permeability) of the baffle plate 24 at the same time, the narrow openings 24 should be formed as finer and as many as possible. An example of a method of manufacturing the baffle plate 24 will be discussed by referring to FIGS. 4A to 4C and FIG. 5.

First, a ring-shaped base member of the buffle plate 24 with a thickness of about 1 mm to 2 mm as shown in FIG. 4A is prepared (step 501).

Next, a photoresist is coated on the major surface of the base member as shown in FIG. 4B. Then the photoresist is exposed using photo-musk having a pattern of the openings, and is patterned (developed) in such a way that the narrow openings 24a having the desired size and the desired shape are formed in the desired quantity in the desired positions (step 502).

Finally, with the patterned photoresist as an etching mask, the base member is photoetched to form the baffle plate 24 having the narrow openings 24a with the desired size and the desired shape formed in the desired quantity in the desired positions as shown in FIG. 4C (step 503). Then, the photoresist is removed.

It is possible to form finer and greater number of narrow openings 24a by photoetching compare to form narrow openings by machining. The opening ratio (=the total area of the narrow holes 24a/the area of the baffle plate 24) of the baffle plate 24 which has the narrow openings 24a formed by photoetching can be greater than the opening ratio of the baffle plate whose narrow openings are formed by machining.

Because the load applied to the base member at the time of forming the narrow openings 24a by photoetching is less than the load applied to the base member at the time of forming the openings by machining, the base member can be made narrower, thereby making it possible to form the baffle plate 24 with a thickness of about 1 mm to 2 mm.

Because the baffle plate 24 has a high opening ratio and is thin, the baffle plate 24 confine the plasma generated between the susceptor 19 the upper electrode, into the upper portion (near the wafer W) of the chamber 12 with having the conductance.

Accordingly, the plasma processing apparatus 11 can process the wafer W with a high plasma-using efficiency.

As shown in FIG. 1, the susceptor 19 comprises an electrode plate 191 and an insulator 192 and serves as a mount table for the wafer W, and serves as the lower electrode. The electrode plate 191 is made of a conductive material, such as aluminum, and the insulator 192 is made of ceramics or the like and is so formed as to cover the electrode plate 191.

The upper center of the susceptor 19 is formed into a convex disc shape and an electrostatic chuck 193 which is of approximately the same shape as the wafer W is provided on the susceptor 19. As a voltage is applied to the electrostatic chuck 193 from a DC (Direct Current) voltage supply 39, the Coulomb's force causes the mounted wafer W to be electrostatically chucked on the susceptor 19.

A first high-frequency electric power supply 25 is connected to the electrode plate 191 via a first matching unit 26. The first high-frequency electric power supply 25 applies a high-frequency voltage (of 0. 1 to 13 MHz) to the electrode plate 191. The application of such a high-frequency voltage can bring about an effect of reducing damages on the wafer W or a work to be processed.

A ring-shaped focus ring 27 is so arranged as to surround the wafer W mounted on the electrostatic chuck 193. The focus ring 27 is made of silicon or the like. The focus ring 27 allows the plasma to be concentrated inside to ensure an efficient and highly uniform plasma process.

The susceptor 19 is provided with unillustrated lift pins for transferring the wafer W. The lift pins can be elevated up and down through the susceptor support 17 and the susceptor 19 by an unillustrated drive motor.

An upper electrode 28 is provided above the susceptor 19 in parallel to, and facing, the susceptor 19. The upper electrode 28 comprises an electrode plate 30 and an electrode support 31 and is supported on the upper portion of the chamber 12 via an insulating member 29.

The electrode plate 30 is formed of, e.g., aluminum, silicon, SiC or amorphous carbon, in parallel to, and facing, the susceptor 19. The electrode plate 30 has multiple gas holes 30a formed in its entire surface.

The electrode support 31, which is welded to the electrode plate 30, is made of a conductive material, such as aluminum. The electrode support 31 has an upper refrigerant chamber 32 inside and has a water-cooled structure. The upper refrigerant chamber 32 is connected to an upper refrigerant pipe 33 so that cooling water can flow inside the upper refrigerant chamber 32. The flow of the cooling water into the upper refrigerant chamber 32 can prevent overheating of the upper electrode 28.

The electrode support 31 has a gas feeding pipe 34 to which a process gas is supplied via a valve, a flow rate control unit or the like. Available as the process gas are gases which can form a SiOF film, such as silane tetrafluoride (SiF₄), monosilane (SiH₄) and oxygen (O₂). The aforementioned gases may be mixed with a rare gas such as argon, helium, or nitrogen.

The electrode support 31 has hollow diffusion portions 31a inside, which are connected to the plural gas openings 30a of the electrode plate 30. The gas that is supplied from the gas source via the gas feeding pipe 34 is diffused by the diffusion portions 31a and is supplied to the gas openings 30a. This allows the gas to be uniformly supplied to the entire surface of the wafer W from the plural gas openings 30a.

A feeder bar 35 made of a conductive material, such as aluminum, is connected to the upper electrode 28. The feeder bar 35 is connected to a second high-frequency electric power supply 37 via a second matching unit 36. The surface of the feeder bar 35 and the surface of the upper electrode 28 are formed to have a proper roughness by shot blasting, in order to enhance the adhesion of an insulating film 41.

The second high-frequency electric power supply 37 supplies (feeds) high-frequency electric power (of 13 to 150 MHz) to the upper electrode 28. This generates a high-density plasma between the upper electrode 28 and the susceptor 19 as the lower electrode.

The insulating film 41 is formed on the surfaces of the upper electrode 28 and the feeder bar 35. The insulating film 41 is made of an insulating material of a low dielectric constant, such as polytetrafluoro-ethylene (PTFE) with porous structure. The insulating film 41 is provided to insulate the upper electrode 28 and the feeder bar 35 from other grounded members. An upper protection member 40 made of the same material as that for the chamber 12 is formed above the chamber 12 which includes the insulating film 41.

The upper protection member 40 which is made of the same material as that of the chamber 12, is formed above the chamber 12. It covers the upper part of the chamber 12, the insulating member 29, the upper electrode 28, the feeder bar 35, and the insulating film 41.

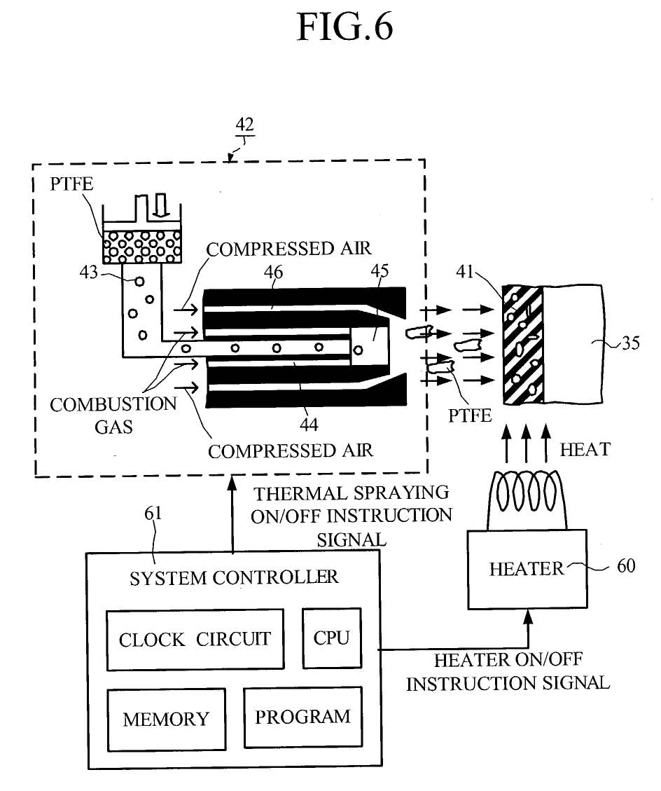

The insulating film 41 is formed by an insulating film forming system shown in FIG. 6.

As shown in FIG. 6, the insulating film forming system comprises a thermal-spraying unit 42, a heater 60 and a system controller 61.

The thermal-spraying unit 42 comprises a source supply pipe 43, a combustion gas supply pipe 44, a compressed air supply pipe 46 and a contact portion 45, as shown in FIG. 6. ON/OFF action of the thermal-spraying is controlled by the system controller 61.

The source supply pipe 43 has an unillustrated valve which can open and close the pipe 43. When the valve open, the source supply pipe 43 supplies the contact portion 45 with a predetermined dose of particulate PTFE per unit time. The valve of the source supply pipe 43 is opened at the time of the thermal-spraying is on(started), and is closed at the time of the thermal-spraying is off(stopped).

The combustion gas supply pipe 44 has an unillustrated valve which can open and close the pipe 44. When the valve opens, the combustion gas supply pipe 44 supplies the contact portion 45 with a combustion gas comprised of a mixture of acetylene and oxygen. The valve of the combustion gas supply pipe 44 is opened at the time of the thermal-spraying is on, and is closed at the time of the thermal-spraying unit 42 is off.

The compressed air supply pipe 46 has an unillustrated valve which can open and close the pipe 46. When the valve opens, the compressed air supply pipe 46 supplies air compressed to a predetermined pressure (compressed air) to the contact portion 45. The valve of the compressed air supply pipe 46 is opened at the time of the thermal-spraying is on, and is closed at the time of the thermal-spraying is off.

At the contact portion 45, the combustion gas burns, the PTFE supplied from the source gas supply pipe 43 is instantaneously melted into a gel form by the heat of the burn. The gelled PTFE is sprayed toward the surface of the feeder bar 35 or the like from the contact portion 45 by the jet effect of the compressed air supplied from the compressed air supply pipe 46. The sprayed gelled PTFE adheres on the surface of the feeder bar 35 or the like, thereby forming a thermal-sprayed film of PTFE thereon.

The heater 60 performs an annealing process on the PTFE formed on the surface of the feeder bar 35 or the like based on an instruction from the system controller 61.

The system controller 61 comprises a CPU (Central Processing Unit), ROM (Read Only Memory), etc., and incorporates a memory constituted by a RAM (Random Access Memory), and a clock circuit. The system controller 61 has a computer program which calculates the number of repetitions of steps 702 to 712, discussed below, from the predetermined thickness of the thermal-sprayed film and the desired thickness of the insulating film.

The system controller 61 controls the ON/OFF action of the thermal-spraying and the ON/OFF action of the heater 60, measures the timing at which the thermal gas spraying starts and the timing at which the heater 60 is turned on by using the clock circuit and stores the measured timings into the memory.

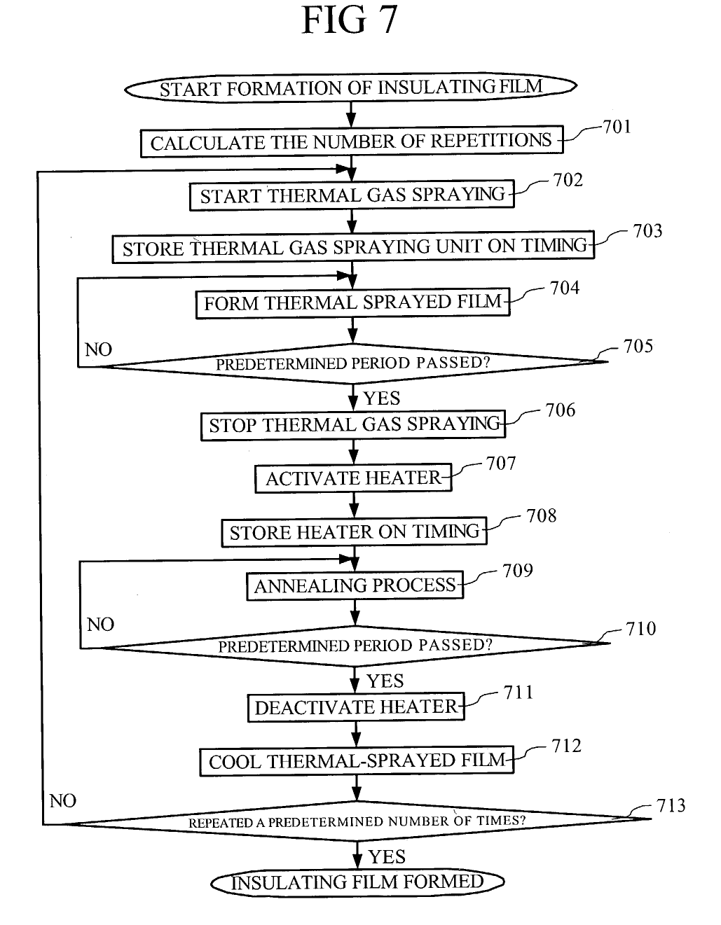

An operation of the insulating film forming system with the above-described structure will be described below referring to a flowchart illustrated in FIG. 7.

As the instruction is communicated to the system controller 61, the system controller 61 responds the instruction and starts the operation shown in FIG. 7.

When the instruction is given, the system controller 61 calculates the number of repetitions of steps 702 to 712, discussed below, based on the predetermined thickness of the thermal-sprayed film and the desired thickness of the insulating film (step 701).

The system controller 61 supplies the thermal gas spraying unit 42 with a thermal-spraying ON instruction signal which instructs the activation of the thermal-spraying. In response to the thermal-spraying ON instruction signal, the thermal-spraying unit 42 opens the valves of the source gas supply pipe 43, the combustion gas supply pipe 44, and the compressed air supply pipe 46. (step 702). As a result, a predetermined dose of PTFE per unit time is supplied to the contact portion 45, and the combustion gas, the compressed air reach the contact portion 45, then the combustion gas burn.

The system controller 61 detects the timing at which the thermal-spraying starts (thermal-spraying ON timing), and stores the detected thermal-spraying ON timing into the memory (step 703).

The PTFE supplied to the contact portion 45 is instantaneously melted to be a gel by the heat of the burn of the combustion gas. The gelled PTFE is sprayed toward the surface of the feeder bar 35 or the like by the jet effect of the compressed air supplied from the compressed air supply pipe 46 and adheres on the surface of the feeder bar 35 or the like. The PTFE adhered on the surface or the like of the feeder bar 35 forms a thermal-sprayed film (step 704). As a predetermined dose of PTFE per unit time is supplied to the contact portion 45, the thermal-sprayed film, etc, are formed to have a predetermined thickness per unit time.

After a predetermined period passes since the thermal-spraying ON timing (YES in step 705), the system controller 61 supplies the thermal-spraying unit 42 with a thermal-spraying-unit OFF instruction signal which instructs deactivation of the thermal-spraying. In response to the thermal-spraying OFF instruction signal, the thermal-spraying is deactivated (step 706).

After the thermal-spraying is deactivated, the system controller 61 turns on the heater 60 (step 707).

The system controller 61 detects the timing at which the heater 60 is activated (heater ON timing), and stores the measured heater ON timing into the memory (step 708).

As the heater 60 is activated, the thermal-sprayed film formed on the surface of the feeder bar 35 or the like is subjected to an annealing process (step 709). As the annealing process is performed, the thermal-sprayed film is melted, and stress generated on the thermal-sprayed film is eliminated.

After a predetermined period passes since the heater ON timing (YES in step 710), the system controller 61 turns off the heater 60 (step 711). As the heater 60 is deactivated, the melted thermal-sprayed film is air-cooled, and hardened (step 712).

In case where the system controller 61 determines that the steps 702 to 712 are not repeated by the calculated number of times (NO in step 713), the system controller 61 repeats the steps 702 to 712 again.

On the other hand, in case where the system controller 61 determines that the steps 702 to 712 have been repeated by the calculated number of times (YES in step 713), the system controller 61 terminates the operation of the insulating film forming system.

As the steps 702 to 712 are repeated by the number of times calculated from the predetermined thickness of the thermal-sprayed film and the desired thickness of the insulating film, the insulating film 41 with the desired thickness is formed on the surface of the feeder bar 35 or the like. As air is supplied into thermal-sprayed film on the process of thermal-spraying, an insulating film 41 with a porous structure is formed as shown in FIG. 6. As air with a relative dielectric constant of 1 is included into the insulating film 41, the specific dielectric constant of the thermal-sprayed film becomes smaller than the original specific dielectric constant of PTFE. Therefore, the insulating film 41 which is formed by the deposition of such a thermal-sprayed film has a higher insulation performance than the insulating film that is formed of PTFE which is not thermal-sprayed. Further, as an annealing process is performed on the thermal-sprayed film, every time a predetermined thickness is achieved, the thick insulating film 41 can be formed, thereby making it possible to further enhance the insulation performance.

The formation of the insulating film 41 with a high insulation performance can provide excellent insulation between the feeder bar 35 or the like and other grounded members. This can make the distance (insulation distance) between the feeder bar 35 or the like and other grounded members shorter than is provided by the prior art.

As the insulation distance is shortened, the plasma processing apparatus 11 has a small dielectric loss in the chamber 12, etc, and can process the wafer W with a high plasma-using efficiency.

Because the distance between the feeder bar 35 or the like and other grounded members can be made shorter, the plasma processing apparatus 11 can be made compact.

The invention is not limited to the above-described embodiment but can be modified and adapted in various other forms. A description will now be given of modifications of the embodiment that are applicable to the invention.

In the embodiment, the chamber 12 is made of aluminum. The invention is not however limited to this type, and the chamber 12 may be made of stainless steel or the like.

In the embodiment, the bellows 23 made of high-purity nickel or aluminum is used for the lower center portion of the susceptor support 17 (susceptor 19). However, the invention is not limited to this type, and the bellows 23 made of high-purity nickel or aluminum may be used for other portions, such as other members of the chamber 12 which have an elevating mechanism, such as a lift pin, or an elevating mechanism equipped with a manipulator of a wafer transfer system.

In the embodiment, the baffle plate 24 has a flat shape. However, the invention is not limited to this type, and the shape of the baffle plate 24 may be a shape which is inclined by a predetermined angle toward the center direction by deforming a plate-like member of a predetermined shape by etching or a cylindrical shape or the like which has, for example, an L-shaped cross section to surround the susceptor 19.

In the embodiment, the insulating film 41 as a thermal-sprayed film is formed on the surfaces of the feeder bar 35 and the junction between the upper electrode 28 and the feeder bar 35 to insulate the feeder bar 35 or the like from other grounded members. However, the invention is not limited to this type, and the insulating film may be formed on other portions which need insulation, for example, the feedering portion of the lower electrode.

In the embodiment, PTFE is used as the material for the insulating film 41. The invention is not however limited to this type, and any other insulating material may be used as well.

In the embodiment, the thickness of the insulating film 41 to be formed is instructed when the formation of the insulating film 41 is instructed. However, the invention is not limited to this type, and the thickness of the insulating film 41 to be formed may be instructed in the system controller 61 beforehand.

In the embodiment, the system controller 61 calculates the number of repetitions of the steps 702 to 712 at the beginning. However, the invention is not limited to this type, and the number of repetitions of the steps 702 to 712 may be calculated at any time.

In the embodiment, as the system controller 61 calculates the number of repetitions of the steps 702 to 712 based on the predetermined thickness of the thermal-sprayed film and the desired thickness of the insulating film, the insulating film forming system forms the insulating film 41 with the desired thickness on the surface of the feeder bar 35 or the like. However, the invention is not limited to this type, and the system controller 61 may form the insulating film 41 with the desired thickness on the surface of the feeder bar 35 or the like by detecting the thickness of the thermal-sprayed film formed on the surface of the feeder bar 35 or the like and determining based on the detection result whether or not to repeat the steps.

In the above-described embodiment, various improvements have been made on the plasma processing apparatus 11 in order to enhance the high plasma-using efficiency. But, the plasma processing apparatus 11 should not necessarily have those improvements but should have at least one of the improvements.

The chamber 12, the bellows 23 and the baffle plate 24 according to the embodiment are used in the plasma processing apparatus 11 which generates a plasma inside the apparatus and performs a plasma process on a wafer W. But, the invention is not limited to this particular usage, the bellows 23 and the baffle plate 24 according to the embodiment may be used in a remote plasma processing apparatus into which a plasma generated outside the plasma processing apparatus is supplied to perform a plasma process on the wafer W.

Various embodiments and changes may be made thereunto without departing from the broad spirit and scope of the invention. The above-described embodiment is intended to illustrate the present invention, not to limit the scope of the present invention. The attached claims rather than the embodiment show the scope of the present invention. Various modifications made within the meaning of an equivalent of the claims of the invention and within the claims are to be regarded to be in the scope of the present invention.

This application is based on Japanese Patent Application No. 2002-21829 filed on Jan. 30, 2002 and including specification, claims, drawings and summary. The disclosure of the above Japanese Patent Application is incorporated herein by reference in its entirety.

What is claimed is:

1. A plasma processing apparatus comprising:
a process chamber in which a predetermined process is performed on a work;
a first electrode which is arranged in said process chamber and on which said work is to be placed;
a second electrode facing to said first electrode; and
a conductive member which is connected to said second electrode and supplies high-frequency electric power to said second electrode.

2. The plasma processing apparatus according to claim 1, wherein an insulating film with a porous structure is formed on surface of said conductive member and at least a part of a surface of said second electrode onto which said conductive member is connected.

3. The plasma processing apparatus according to claim 1, wherein said conductive member and at least a part of a surface of said second electrode onto which said conductive member is connected have an insulating film formed by thermal-spraying an insulating material onto said conductive member and said at least a part of a surface of said second electrode.

4. The plasma processing apparatus according to claim 2, wherein said insulating film is formed by:
performing thermal spray of an insulating material onto said conductive member and said at least a part of said second electrode to form a thermal-splayed film; and
annealing the thermal-sprayed film every time the thermal-sprayed film with a predetermined thickness is formed.

5. The plasma processing apparatus according to claim 3, wherein said insulating material is comprised of PTFE (Poly Tetra Fluoro Ethyrene).

6. The plasma processing apparatus according to claim 3, wherein surfaces of said conductive member and said at least a part of said second electrode have a predetermined roughness in order to enhance adhesion of the insulating thermal-sprayed material.

7. The plasma processing apparatus according to claim 3, wherein surfaces of said conductive member and said at least a part of said second electrode have a predetermined roughness by shotblasting.

8. The plasma processing apparatus according to claim 1, wherein said process chamber is manufactured by:
smoothing an inner surface of a cylindrical base member by mechanical working;
etching out cracks formed on said inner surface of said base member by said smoothing, the crack being formed by said mechanical working; and
forming an insulating film on said inner surface of said base member after said cracks have been etched out.

9. The plasma processing apparatus according to claim 8, wherein said insulating film is a metal oxide film formed by anodizing.

10. The plasma processing apparatus according to claim 8, wherein said base member is made of aluminum and said insulating film is an aluminum oxide film.

11. The plasma processing apparatus according to claim 1, further comprising a bellows which connects a bottom portion of said process chamber and said first electrode, said bellows being formed of high-purity aluminum, nickel, or alloy thereof.

12. The plasma processing apparatus according to claim 1, further comprising a baffle plate which is provided inside said process chamber and traps a generated plasma in a predetermined area in said process chamber, and said baffle plate being manufactured by:
forming a photoresist film on a base member and patterning said photoresist film to have a plurality of openings; and
forming a plurality of openings by etching said base member using said patterned photoresist film as an etching mask.

13. A plasma processing apparatus comprising:
an electrode facing to a susceptor on which a work is to be placed;
a conductive member which is connected to said electrode and feeds high-frequency electric power to said electrode; and
an insulating film formed on said conductive member and at least a part of a surface of said electrode onto which said conductive member is connected;
said insulating film being formed by thermal-spraying an insulating material onto said conductive member and said at least a part a surface of said electrode.

14. A plasma processing apparatus having a process chamber and performing a predetermined process on a work in said process chamber, said process chamber being manufactured by:
smoothing an inner surface of a cylindrical base member by mechanical working;
etching out cracks formed on said inner surface of said base member, the crack being formed by said mechanical working; and
forming an insulating film on said inner surface of said base member after said cracks have been etched out.

15. A plasma processing apparatus comprising:
a process chamber in which a predetermined process is performed on a work;
an electrode which is arranged in said process chamber and on which said work is placed; and
a bellows which is connected to a bottom portion of said process chamber and said electrode;
said bellows being formed of high-purity aluminum, nickel, or alloy thereof.

16. A plasma processing apparatus comprising:
a process chamber in which a predetermined process is performed on a work; and
a baffle plate which is provided inside said process chamber and traps a generated plasma in a predetermined area in said process chamber,
said baffle plate being manufactured by:
forming a photoresist film on a base member and patterning said photoresist film to have a plurality of openings; and
forming a plurality of openings by etching said base member using said patterned photoresist film as an etching mask.

17. An insulating film forming system comprising:
a thermal spray unit which thermal-sprays an insulating material toward a target;
a heating unit which heats up the thermal-sprayed material adhered to said target; and
a control unit which performs a first control operation that makes said thermal spray unit to thermal-spray the insulating material toward the target during a predetermined time period so that an insulating film with a predetermined thickness is formed on the target, then performs a second control operation that makes said heating unit to heat the insulating film on the target during a predetermined time period so that said insulating film is melted and then cooling down the melted insulating film so that the insulating film is hardened, and repeats the first and second control operations until the insulating film having a desired thickness is formed on the target.

18. The insulating film forming system according to claim 17, wherein said control unit calculates, from said predetermined thickness and said desired thickness, number of times said first and second control operations should be repeated, and repeats the first and second control operations by the calculated number of times.

19. An insulating film forming method comprising:
thermal-spraying insulating material toward a target during a predetermined time period so that an insulating film with a predetermined thickness is formed on the target,
heating the insulating film on the target during a predetermined time period so that said insulating film is melted and then cooling down the melted insulating film so that the insulating film is hardened.

20. The insulating film forming method according to claim 19, wherein said thermal-spraying, said melting, and said cooling are repeated until the insulating film having a desired thickness is formed on the target.

21. A bellows, which is connected to, at one end, a bottom portion of a process chamber in which a predetermined process is performed on a work, and connected to, at another end, an electrode which is arranged in said process chamber and supports the work, maintains the vacuum state inside of said chamber thereby said predetermined process can be performed,
said bellows being formed of high-purity aluminum, nickel, or alloy thereof.

22. A method of forming an insulating film comprising:
performing thermal spray of an insulating material onto a conductive member which is connected to an electrode supporting a work and feeds high-frequency electric power to said electrode, and onto at least a part of a surface of said electrode onto which said conductive member is connected, to form a thermal-sprayed film; and
annealing the thermal-splayed film every time the thermal-sprayed film with a predetermined thickness is formed.

23. A method of manufacturing a process chamber of a plasma processing apparatus wherein a predetermined process using a plasma is performed on a work, comprising:
smoothing an inner surface of a cylindrical base member by mechanical working;
etching out cracks formed on said inner surface of said base member, the crack being formed by said mechanical working; and
forming an insulating film on said inner surface of said base member after said cracks have been etched out.

24. A method of manufacturing a baffle plate which is provided inside a process chamber of a plasma processing apparatus for generating a plasma, performing a predetermined process on a work in said process chamber with the generated plasma, and traps a generated plasma in a predetermined area in said process chamber, comprising:
forming a photoresist film on a base member and patterning said photoresist film to have a plurality of openings; and
forming a plurality of openings by etching said base member using said patterned photoresist film as an etching mask.
